(19) United States
(12) Patent Application Publication
(10) Pub. No.: US 2026/0106575 A1
(43) Pub. Date: Apr. 16, 2026

(54) IMPLEMENTATION METHOD OF NOVEL LOW-DISTORTION DIGITALLY MODULATED DIRECT-DRIVE POWER AMPLIFIER APPARATUS

(71) Applicant: SPIC NUELECTRONIC(WUXI) COMPANY LIMITED, WUXI (CN)

(72) Inventors: HAORAN FU, WUXI (CN); ZHIYU WANG, WUXI (CN); WEI LIU, WUXI (CN); JIAQI YANG, WUXI (CN); XIAOWEI CAI, WUXI (CN); XUDONG WANG, WUXI (CN); GANGJIA ZHAI, WUXI (CN); HUINA MENG, WUXI (CN); XUFENG LI, WUXI (CN)

(21) Appl. No.: 19/329,506

(22) Filed: Sep. 15, 2025

Related U.S. Application Data
(63) Continuation-in-part of application No. PCT/CN2025/088478, filed on Apr. 11, 2025.

(30) Foreign Application Priority Data
Oct. 16, 2024 (CN) 202411442074.0

(51) Int. Cl. H03F 1/32; H03F 3/24

(52) U.S. Cl. CPC H03F 1/32; H03F 3/245; H03F 2200/451

(57) ABSTRACT

Provided is an implementation method of a novel low-distortion digitally modulated direct-drive power amplifier apparatus. The method can achieve acquisition of modulated waveform signals by Δ-Σ oversampling technique, and further improves a sampling rate of the modulated waveform signals by an interpolated filter. An exciter can generate multiphase PDM modulated waveform pulses and carrier drive pulses to directly drive power amplifier modules to complete carrier generation and waveform modulation. However, to reduce complexity of a system and take the modulated waveform THD indicators into account, the multiph [symbol] controlled within 12 phases.

### CROSS-REFERENCE TO RELATED APPLICATION

This application is a continuation-in-part of and claims priority to International Application No. PCT/CN 2025/088478, filed on Apr. 11, 2025, which claims the priority of Chinese Patent Application No. 202411442074.0 filed with the China National Intellectual Property Administration on Oct. 16, 2024, and entitled “Implementation method of novel low-distortion digitally modulated direct-drive power amplifier apparatus”, both of which are incorporated by reference in this application.

### TECHNICAL FIELD

The present disclosure relates to the field of plasma-generated radio frequency power supply, and in particular to an implementation method of a novel low-distortion digitally modulated direct-drive power amplifier apparatus.

### BACKGROUND

Plasma is a material form mainly composed of free electrons and charged particles, which exists widely in the universe and is called a fourth state of matter. The plasma has high conductivity, is rich in high-energy electrons, ions and a large number of active substances, and has a wide range of application scenarios in food processing, metal smelting, environmental governance, biomedicine, semiconductor etching and thin film deposition, surface cleaning, aerospace and other fields. During actual application of the plasma, a special power supply for generating plasma is the core, which generally includes a high-voltage direct current power supply, a high-voltage pulse power supply, a high-frequency alternating current power supply and a radio frequency power supply, among which the radio frequency power supply is dominant in nuclear technology industry and semiconductor manufacturing industry. When the radio frequency power supply is excited to generate plasma, large reflected signals will be generated at an initial stage of plasma establishment due to the drastic changes of load impedance, which has a significant harm to the radio frequency power supply. To reduce the harm of the reflected signals to the radio frequency power supply, radio frequency signals modulated initially with trapezoidal waves or exponential function waves are generally established to reduce the accumulation of reflected energy at the initial stage of plasma establishment in a short time.

At present, there are related patents in the industry that disclose the patented technology of how to perform low-distortion power amplification. In patent application No. 202110545047.6, an implementation method of a high-power low-distortion D-type power amplifier based on a high-performance MCU (microcontroller unit) is provided, which includes main steps as follows: (1) selecting and displaying an input signal pattern; (2) preprocessing input signals to obtain audio data; (3) transmitting the audio data to STM32F407 minimum system, and outputting PWM (pulse-width modulation) to half-bridge driver modules; (4) driving a full-bridge power amplification part by every two half-bridge driver modules to achieve power amplification of small signals; (5) filtering output of the full-bridge power amplification part; (6) sampling current of output from a low-pass filter, and feeding the sampled current back to the minimum system; (7) setting a digital filter according to output feedback signals, and filtering the audio data in (1); and (8) repeating step (2) to step (7) to achieve negative feedback control of output. The disclosure reduces noise interference in class-D power amplifiers during power-on at low cost, and perform high frequency compensation through IIR (infinite impulse response), thereby solving the problem that the class-D power amplifier has high requirements for a filter when a switching frequency is low.

However, this disclosure patent provides an implementation method of a novel low-distortion digitally modulated direct-drive power amplifier apparatus. This method enables the implementation of a digitally modulated direct-drive radio frequency power supply for plasma generation by a novel technology, a novel architecture and a novel configuration.

### SUMMARY

For the problems in a method known by the inventor, an objective of the present disclosure is to provide an implementation method of a novel low-distortion digitally modulated direct-drive power amplifier apparatus to solve the problems mentioned in the background, and the method can enable the implementation of a digitally modulated direct-drive radio frequency power supply for plasma generation by a novel technology, a novel architecture and a novel configuration.

The present disclosure is implemented by adopting the following technical solution: an implementation method of a novel low-distortion digitally modulated direct-drive power amplifier apparatus includes an exciter, configured to acquire and process signals in different waveform formats and generate multiphase PDM (pulse-duration modulation) modulated waveform pulses and carrier drive pulses; and a PDM pulse distribution unit, configured to further improve a sampling rate of modulated waveform signals. The method can achieve acquisition of modulated waveform signals by Δ-Σ oversampling technique, and a sampling rate of the modulated waveform signals is further improved by an interpolated filter; the exciter can generate multiphase PDM modulated waveform pulses and carrier drive pulses to directly drive power amplifier modules to complete carrier generation and waveform modulation.

The present disclosure has the following beneficial effects. The exciter provided by the present disclosure receives modulated waveform signals in various formats (analog signals, digital signals and text signals) sent from the outside, where the digital signals and text signals are digitally modulated waveform signals, with a sampling rate of 48 kHz in general; the analog modulated waveform signals are subjected to analog-to-digital conversion through a modulated waveform AD (analog-to-digital) chip, and a sampling rate of the modulated waveform AD chip is 96 kHz in general. Therefore, to make FPGA (field-programmable gate array) processing convenient and save FPGA logic resource, the sampling rate of the modulated waveform is 48 kHz, so that the digitally modulated waveform signals are converted into 48 kHz by modulation waveform rate/format conversion and then sent to the FPGA, and a format of the currently input modulated waveform can be selected by an upper computer/dip switch. The number n of phases can be selected through the upper computer/dip switch, and the sampling rate of the 48 kHz modulated waveform signals is increased to 0.048×N kHz through an interpolated filter in the FPGA. Because a frequency of the radio frequency ranges from 500 kHz to 15 MHz, the higher the selected number of phases, the easier it is to filter out sampling switching frequencies. By comparing the interpolated 0.048×N kHz modulated waveform signals with single-phase triangular wave signals, PDM pulse signals with a pulse width proportional to an amplitude of the modulated waveforms are obtained. If 6-phase modulation is selected here, a frequency of triangular wave signals are 48 kHz×6=288 kHz.

As shown in FIG. 2 and FIG. 3 of the specification, the modulated waveform signals in FIG. 2 and FIG. 3 of the specification are simultaneously input into different comparators, and a phase difference between adjacent triangular wave signals among N triangular wave signals is 360°/N. After passing through the comparators, the multiphase PDM modulation of the modulated waveforms are achieved. Components of the modulated waveforms are in parallel, and high-frequency noise signals generated by modulation are in frequency superposition, so a harmonic frequency is improved. This frequency superposition helps achieve the miniaturization of a low-pass filter. Multiphase PDM modulation can achieve better modulation waveform THD (Total Harmonic Distortion) indicators to ensure that the modulated waveform signals can be basically recovered without distortion. However, to reduce complexity of a system and take the modulated waveform THD indicators into account, the multiphase PDM modulation is generally controlled within 12 phases. In addition, the modulated waveform signals are divided into multiple equal-amplitude PDM square wave signals by the multiphase PDM modulation and superposition technique, which makes a power amplifier operate in an on-off state and can improve efficiency of the power amplifier.

### BRIEF DESCRIPTION OF THE DRAWINGS

The present disclosure is further described below with reference to accompanying drawings and embodiments.

FIG. 1 is a schematic block diagram of a system according to one or more embodiments;

FIG. 2 is a schematic block diagram of PDM signals generated by modulated waveform processing of an exciter according to one or more embodiments;

FIG. 3 is a schematic block diagram of generation of multi-phase PDM signals according to one or more embodiments;

FIG. 4 is a schematic block diagram of generation of single-phase PDM signals according to one or more embodiments;

FIG. 5 is a schematic block diagram of generation of three-phase PDM signals according to one or more embodiments;

FIG. 6 is a schematic block diagram of generation of nine-phase PDM signals according to one or more embodiments;

FIG. 7 is a schematic block diagram of PDM modulation of a single power amplifier module according to one or more embodiments;

FIG. 8 is a schematic block diagram of an H bridge of a single power amplifier module according to one or more embodiments.

### DETAILED DESCRIPTION OF THE EMBODIMENTS

To make the technical means, creative features, goals and effects of the present disclosure easy to understand, the present disclosure is further set forth with specific illustrations. It should be noted that the embodiments in the present disclosure and the features in the embodiments can be combined with each other without conflict.

### Embodiment 1

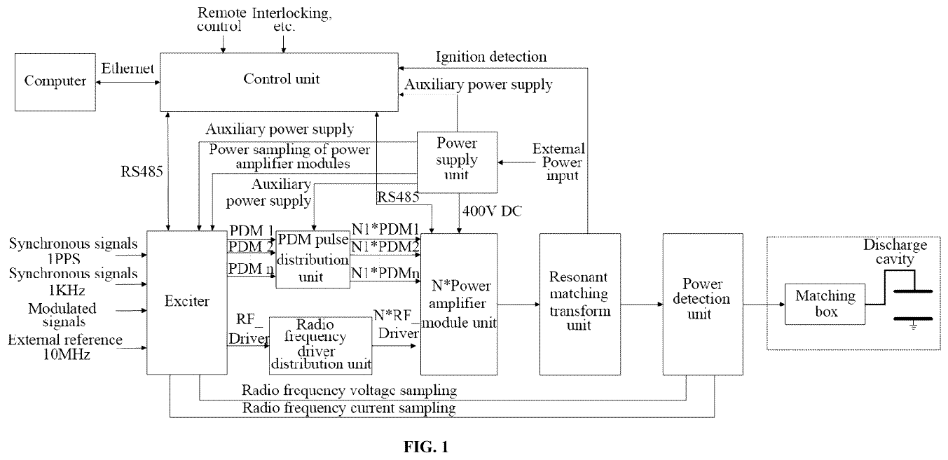

Please referring to FIG. 1, a system schematic block diagram of an implementation method of a novel low-distortion digitally modulated direct-drive power amplifier apparatus is provided.

An implementation method of a novel low-distortion digitally modulated direct-drive power amplifier apparatus includes an exciter and a PDM pulse distribution unit. The exciter is configured to acquire and process signals in different waveform formats and generate multiphase PDM modulated waveform pulses and carrier drive pulses.

The PDM pulse distribution unit is configured to further improve a sampling rate of modulated waveform signals.

The method achieves acquisition of modulated waveform signals by Δ-Σ oversampling technique, and further improves a sampling rate of the modulated waveform signals by an interpolated filter. The exciter can generate multiphase PDM modulated waveform pulses and carrier drive pulses to directly drive power amplifier modules to complete carrier generation and waveform modulation.

Please referring to FIG. 1, the apparatus includes an exciter, a control unit, a PDM pulse distribution unit, a radio frequency driver distribution unit, a power supply unit, a power amplifier module unit, a matching transform unit, a power detection unit, a matching box, a cavity, etc. RS (recommended standard) 485 is a communication interface.

Continuing to refer to FIG. 1, the exciter is mainly configured to acquire and process signals in various formats (analog signals, digital signals and text signals), generate n channels of multiphase PDM modulated waveform drive signals, generate radio frequency drive signals, switch between internal and external clock references, sample and acquire radio frequency voltage and current, and sample and acquire a power supply of power amplifier modules. In FIG. 1, synchronous signals are input into the exciter at 1 pps, synchronous signals are input to the exciter at a frequency of 1 kHz, and external reference signals (10 MHz) are also input for internal and external clock reference switching. PDM 1, PDM 2 . . . . PDM n are n channels of multiphase PDM modulated waveform drive signals generated by the exciter.

Continuing to refer to FIG. 1, the PDM pulse distribution unit is mainly configured to distribute and send the n channels of PDM modulated waveform drive signals generated by the exciter into a BUCK (a buck converter circuit) circuit of the power amplifier module unit to generate modulation voltages of the modulated waveforms. That is, N1*PDM 1, N1*PDM 2 . . . . N1*PDM n are distributed and sent into the power amplifier module unit.

Continuing to refer to FIG. 1, the radio frequency driver distribution unit is mainly configured to distribute and send RF drive signals (RF_Driver) generated by the exciter to an H-bridge circuit of the power amplifier module unit to generate carrier voltage. That is, N*RF_Driver is sent into the power amplifier module unit.

Continuing to refer to FIG. 1, the matching transform unit is configured to complete impedance changes and specific frequency suppression through a T-shaped impedance matching and suppression network.

Continuing to refer to FIG. 1, the power supply unit is mainly configured to, after rectifying and filtering the external incoming power, generate a 400 V voltage required by an input of the BUCK of the power amplifier module unit and an auxiliary power supply (such as ±15 V, +5 V, etc.) required by other systems of the whole apparatus.

Continuing to refer to FIG. 1, the control unit is configured to complete state reading and logic control of all subsystems of the system, as well as external interlocking control and long-distance remote control. To ensure reliability of the system, the long-distance remote control adopts common IO (input/output) port control instead of communication form control, which can greatly reduce abnormal shutdown caused by unreliability of communication. The control unit is connected to a computer through Ethernet to achieve communication connection. The subsystem refers to an exciter, a control unit, a PDM pulse distribution unit, a radio frequency driver distribution unit, a power supply unit, a power amplifier module unit, a resonant matching transform unit, a power detection unit, a matching box, etc.

### Embodiment 2

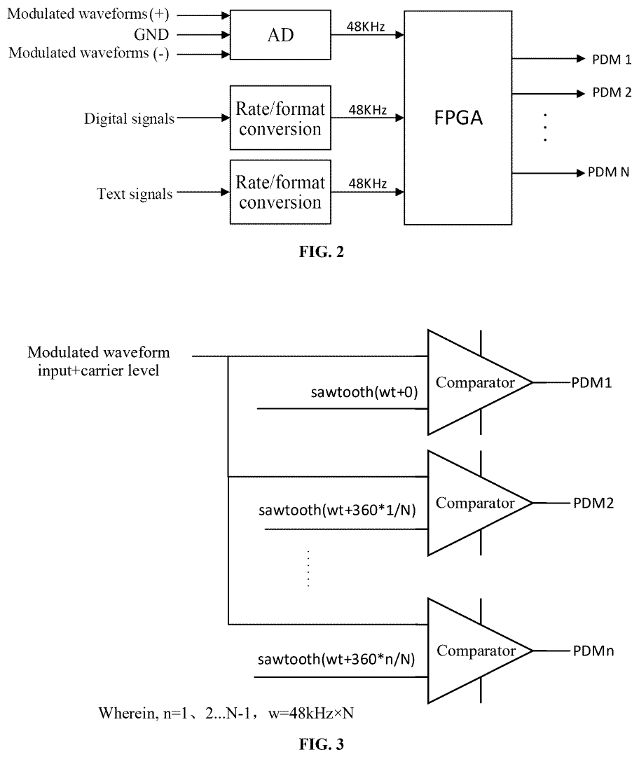

Please referring to FIG. 2 to FIG. 8, this embodiment is similar to Embodiment 1 described above, and the similarities are not be described in this embodiment, but the specific differences are as follows.

Please referring to FIG. 2, the exciter provided by the present disclosure receives modulated waveform signals in various formats (analog signals, digital signals and text signals) sent from the outside, where the digital signals and text signals are digitally modulated waveform signals, with a sampling rate of 48 kHz in general; the analogously modulated waveform signals are subjected to analog-to-digital conversion through a modulated waveform AD (analog-to-digital) chip, and a sampling rate of the modulated waveform AD chip is 96 kHz in general. Therefore, to make FPGA (field-programmable gate array) processing convenient and save an FPGA logic resource, the sampling rate of the modulated waveform is 48 kHz, thus the digitally modulated waveform signals are converted into 48 kHz by modulation waveform rate/format conversion and then sent to the FPGA, and a format of the currently input modulated waveforms can be selected by an upper computer/dip switch. The number n of phases can be selected through the upper computer/dip switch, and the sampling rate of the 48 kHz modulated waveform signals is increased to 0.048×N kHz through an interpolated filter in the FPGA. Because a frequency of the radio frequency ranges from 500 kHz to 15 MHz, the higher the selected number of phases, the easier it is to filter out sampling switching frequencies. By comparing the interpolated 0.048×N kHz modulated waveform signal with a single-phase triangular wave signal, a PDM pulse signal with a pulse width proportional to an amplitude of the modulated waveform is obtained. If 6-phase modulation is selected here, a frequency of a triangular wave signal is 48 kHz×6-288 kHz.

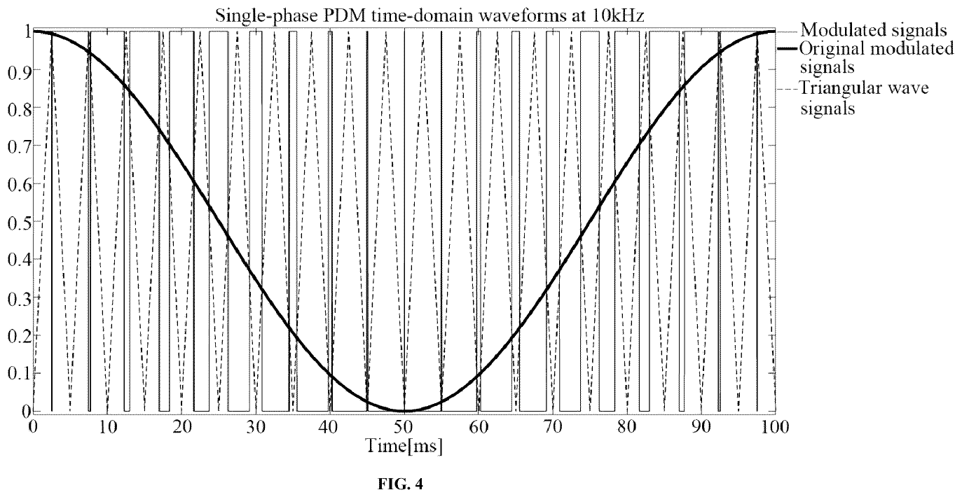

Please referring to FIG. 3, the modulated waveform signals are simultaneously input into different comparators, and a phase difference between adjacent triangular wave signals among N triangular wave signals is 360°/N. After passing through the comparators, the multiphase PDM modulation of the modulated waveforms is achieved. Components of the modulated waveforms are in parallel, and high-frequency noise signals generated by modulation are in frequency superposition, so a harmonic frequency is improved. This helps achieve the miniaturization of a low-pass filter. Multiphase PDM modulation can achieve better modulation waveform THD (Total Harmonic Distortion) indicators to ensure that the modulated waveform signals can be basically recovered without distortion. However, to reduce complexity of a system and take the modulated waveform THD indicators into account, the multiphase PDM modulation is generally controlled within 12 phases. In addition, the modulated waveform signals are divided into multiple equal-amplitude PDM square wave signals by the multiphase PDM modulation and superposition technique, which makes a power amplifier operate in an on-off state and can improve efficiency of the power amplifier. N triangular wave signals are expressed as sawtooth (wt+0), sawtooth (wt+360×1/N) . . . sawtooth (wt+360×n/N), where n=1, 2, . . . , N−1, w=48 kHz×N.

Please referring to FIG. 4, a PDM pulse signal with a pulse width proportional to an amplitude of the modulated waveform signal is generated by comparing the modulated waveform signal with the triangular wave signal.

### Embodiment 3

Please referring to FIG. 2 to FIG. 8, this embodiment is similar to Embodiment 1 and Embodiment 2 described above, and the similarities are not be described in this embodiment, but the specific differences are as follows.

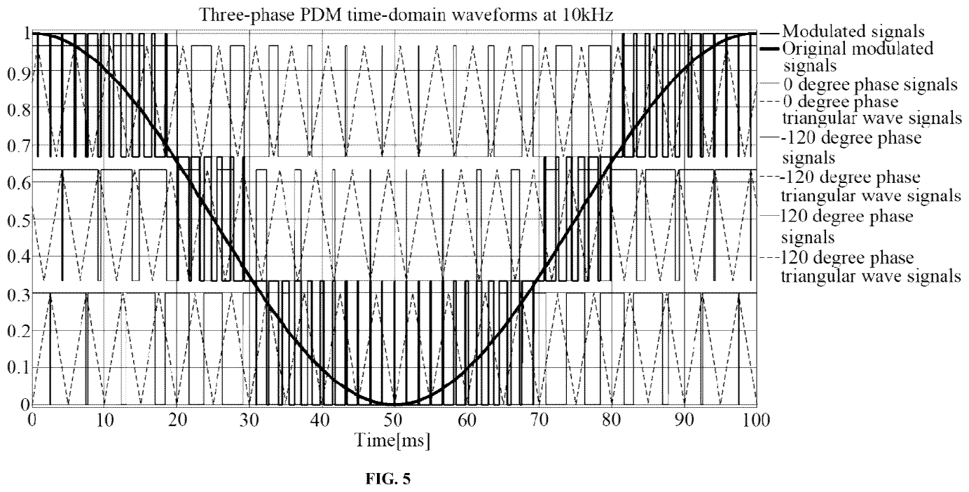

Please referring to FIG. 5, the difference between adjacent triangular waves of the three triangular wave signals is 120°, which is equivalent to that an interval between the triangular wave signals is 120°. An amplitude of the PDM pulse is determined by the number of times that the amplitude of the modulated waveforms exceed that of the triangular waves at a given moment. Because it is a three-phase PDM, a PDM amplitude after final synthesis is 3 at the maximum and 0 at the minimum. The higher the PDM amplitude, the greater the modulated waveform signal. On the contrary, the lower the PDM amplitude, the smaller the modulated waveform signal.

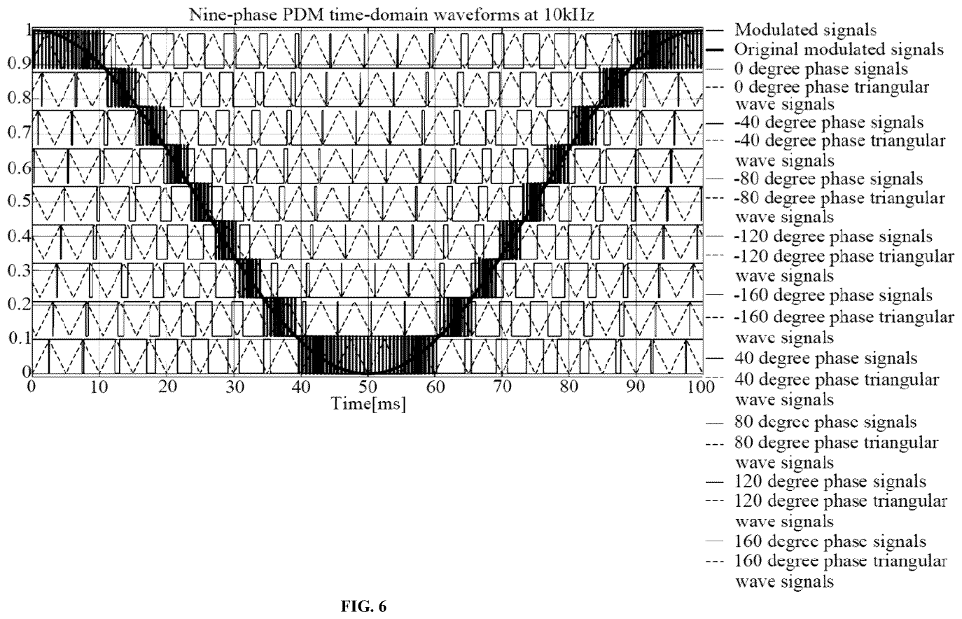

Please referring to FIG. 6, the difference between adjacent triangular wave signals among nine triangular wave signals is 40°, which is equivalent to that an interval between the triangular wave signals is 40°. An amplitude of the PDM pulse is determined by the number of times that the amplitude of the modulated waveforms exceed that of the triangular waves at a given moment. Because it is a nine-phase PDM, a PDM amplitude after final synthesis is 9 at the maximum and 0 at the minimum. The higher the PDM amplitude, the greater the modulated waveform signal. On the contrary, the lower the PDM amplitude, the smaller the modulated waveform signal.

The exciter is configured to generate multiphase PDM modulated waveform pulse signals, and the power amplifier modules are configured to complete the modulation of multiphase PDM signals. The multiphase here generally refers to two phases, four phases, six phases, nine phases, twelve phases, and sixteen phases.

### Embodiment 4

Please referring to FIG. 2 to FIG. 8, this embodiment is similar to Embodiment 1, Embodiment 2 and Embodiment 3 described above, and the similarities are not be described in this embodiment, but the specific differences are as follows.

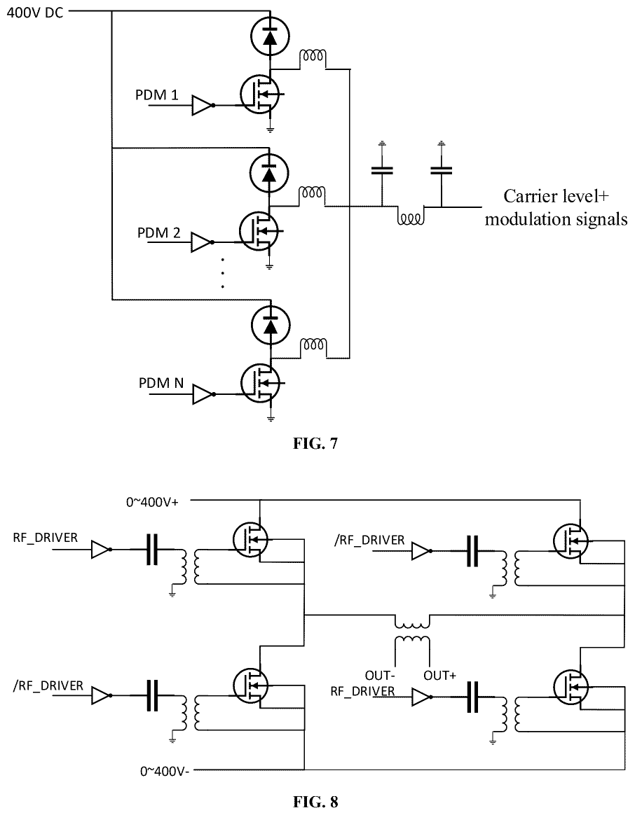

Please referring to FIG. 7, N in FIG. 7 denotes the number of phases of a single module. In general, to reduce the complexity of PDM modulation of a single power amplifier module and take flexible application of a single module (a single module may separately become a system power amplifier) into account, N is equal to 3 or 4 in general. After the number of phases of the single module is determined, the number of phases of the PDM of the whole apparatus is an integer multiple of 3 or 4. By taking a situation that the number of phases of a single module PDM is 4 as an example, to get better modulated waveform distortion, sixteen-phase/twelve-phase PDM can be selected for the whole apparatus, so that every 4/3 power amplifier modules are a group.

When there is no modulation of the modulated waveforms, the modulation of the carrier level is completed by adjusting a fixed duty ratio of the PDM, the higher the duty ration, the higher the carrier level, the lower the duty ratio, the lower the carrier level. A waveform modulation formula is as follows:

$${S}_{AM} ( t ) = [ {A}_{0} + {A}_{m} cos Ω t ] ( cos {ω}_{c} t + {θ}_{c} ) = {A}_{0} [ 1 + m cos Ω t ] ( cos {ω}_{c} t + {θ}_{c} ) \qquad ( formula 1 )$$

$$where m = \frac{{A}_{m}}{{A}_{0}} ,$$

m denotes a modulation depth, S_{AM}(t) is modulated carrier level, A₀ is a carrier amplitude, Aₘ is a carrier amplitude, cos 22t is a modulated signal, cos ω_{c}t is a carrier signal, and θ_{c} is an initial phase angle.

As an input of the BUCK is 400 V, +/−100% modulation can be met only when the carrier level does not exceed 200 V, so the duty ratio of the PDM does not exceed 50%, the carrier level is equivalent to that a direct current bias is added to the modulated waveforms. The carrier level and the modulated waveform level are superimposed and compared with the triangular waves to generate PDM pulses including amplitude information and information of the modulated waveforms of the carriers. Then, the frequency information and phase information of the carriers are mainly completed by an inverter H-bridge circuit behind the BUCK circuit in the power amplifier module. The exciter is configured to output radio frequency drive signals which are distributed to each power amplifier module through a radio frequency driver distribution board to complete the control of the H-bridge circuit. A frequency of H-bridge drive pulse signals is the carrier frequency. If it needs to be synchronized with other devices, rising edges of the H-bridge drive pulse signals need to be synchronized with the synchronous signals.

Please referring to FIG. 8, dead time of the H-bridge and the H-bridge drive pulse signals are generated by the radio frequency drive signals through the processing circuit, and the dead time is controlled at tens of ns, thereby meeting a requirement that the frequency of the radio frequency power supply for plasma generation ranges from 500 kHz to 15 MHz.

A single power amplifier module can be designed to have an output of 2.5 kW, which supports three-phase/four-phase PDM modulation, and three/four power amplifier modules support nine-phase/twelve-phase/sixteen-phase PDM modulation. According to the required power of the whole apparatus, the combined module can achieve an output power of the whole apparatus ranging from 2 kW to 400 kW. If a higher power output is needed, a MW (megawatt)-level output power can be achieved by parallel arrangement. The high-efficiency and low-distortion radio frequency power supply can be achieved through multiphase PDM modulation and switching amplifiers, and the power amplifier efficiency is more than 90% and degree of distortion is less than 1%.

In addition, the PDM in the present disclosure is a modulation method for providing analog signals in a digital field. In the PDM signals, logic “1” indicates a single pulse, and logic “0” indicates that there is no pulse. In general, the logic “1” and the logic “0” are discontinuous, and logic “1” is relatively uniformly distributed in each modulation signal cycle. Single pulse does not indicate the amplitude, while density of a series of pulses corresponds to the amplitude in the analog signals. A PDM signal composed entirely of “1” corresponds to a voltage with a positive amplitude; while a PDM signal composed entirely of “0” corresponds to a voltage with a negative amplitude, and a PDM signal composite alternately of “1” and “0” corresponds an intermediate amplitude.

The basic principle, main features and advantages of the present disclosure have been shown and described above. It should be understood by those skilled in the art that the present disclosure is not limited by the above embodiments, the embodiments described above and description in the specification merely illustrate the principles of the present disclosure, and various changes and improvements can be made to the present disclosure without departing from the spirit and scope of the present disclosure, all of which shall fall within the scope of protection of the present disclosure. The scope of the present disclosure is defined by the appended claim and their equivalents.

1-8. (canceled)

9. An implementation method of a novel low-distortion digitally modulated direct-drive power amplifier apparatus, comprising:
an exciter, configured to acquire and process signals in different waveform formats and generate multiphase PDM (pulse-duration modulation) modulated waveform pulses and carrier drive pulses; and
a PDM pulse distribution unit, configured to further improve a sampling rate of modulated waveform signals;
wherein the method achieves acquisition of the modulated waveform signals by Δ-Σ oversampling technique, and further improves the sampling rate of the modulated waveform signals by an interpolated filter of a PDM pulse distribution unit; the exciter generates the multiphase PDM modulated waveform pulses and the carrier drive pulse to directly drive power amplifier modules to complete carrier generation and waveform modulation;
wherein the exciter is configured to acquire and process the signals in different waveform formats, generate n channels of multiphase PDM modulated waveform drive signals, generate radio frequency drive signals, switch between internal and external clock references, sample and acquire radio frequency voltage and current, and sample and acquire a power supply for the power amplifier modules;
wherein the implementation method of the novel low-distortion digitally modulated direct-drive power amplifier apparatus further comprises a matching transform unit, and the matching transform unit is configured to complete impedance changes and specific frequency suppression through a T-shaped impedance matching and suppression network; and
wherein the implementation method of the novel low-distortion digitally modulated direct-drive power amplifier apparatus further comprises a power supply unit, and the power supply unit is configured to generate voltage required by an input of a BUCK of a power amplifier module unit as well as an auxiliary power supply required by other systems of the whole apparatus after rectifying and filtering an external power input.

10. The implementation method of the novel low-distortion digitally modulated direct-drive power amplifier apparatus according to claim 9, wherein the PDM pulse distribution unit is configured to distribute and send n channels of PDM modulated waveform drive signals generated by the exciter into a BUCK circuit of a power amplifier module unit to generate modulation voltage of modulated waveforms.

11. The implementation method of the novel low-distortion digitally modulated direct-drive power amplifier apparatus according to claim 9, further comprising a radio frequency driver distribution unit, wherein the radio frequency driver distribution unit is configured to distribute and send radio frequency drive signals generated by the exciter into an H-bridge circuit of a power amplifier module unit to complete generation of carrier voltage.
